(19) United States
(12) Patent Application Publication
(10) Pub. No.: US 2011/0116239 A1
(43) Pub. Date: May 19, 2011

(54) Locking Mechanisms for Retaining Two Swinging Panels and Apparatus and Enclosures Including a Locking Mechanism for Retaining Two Swinging Panels

(75) Inventors: Simon Shen-Meng Chen, Palatine, IL (US); Eduardo Leon, Woodridge, IL (US); George I. Wakileh, Batavia, IL (US)

(73) Assignee: Emerson Network Power, Energy Systems, North America, Inc., Warrenville, IL (US)

(21) Appl. No.: 12/948,296

(22) Filed: Nov. 17, 2010

Related U.S. Application Data
(60) Provisional application No. 61/262,018, filed on Nov. 17, 2009.

(51) Int. Cl. H05K 7/16; E05C 7/00

(52) U.S. Cl. 361/726; 292/16

(57) ABSTRACT

A telecommunications enclosure including a housing is disclosed. A first panel is operatively coupled to the housing for pivotal movement between a first position and a second position. A second panel is operatively coupled to the housing for pivotal movement between a first position and a second position. The telecommunications enclosure includes a lock operable to retain the first panel in the first position when the second panel is in the second position and to retain the second panel in the first position when the first panel is in the second position. The telecommunications enclosure includes at least one fiber optic splitter mounted on the first panel and a termination field mounted on the second panel.

### CROSS-REFERENCE TO RELATED APPLICATIONS

This application claims the benefit of U.S. Provisional Application No. 61/262,018, filed on Nov. 17, 2009. The entire disclosure of the above application is incorporated herein by reference.

### FIELD

The present disclosure relates to locking mechanisms for retaining two swinging panels and apparatus and enclosures including a locking mechanism for retaining two swinging panels.

### BACKGROUND

This section provides background information related to the present disclosure which is not necessarily prior art.

Fiber optic data transmission is frequently used for transmitting data short and long distances. Telecommunications terminals are often used for distribution of fiber optic cable and services. Such telecommunications terminals can be located in an interior of a building or exterior to any building. Example telecommunications terminals include fiber distribution hubs (FDHs). Fiber optic cables often enter a telecommunications terminal and may be split and distributed, connected/distributed without splitting, etc.

### SUMMARY

This section provides a general summary of the disclosure, and is not a comprehensive disclosure of its full scope or all of its features.

According to one aspect of this disclosure, an apparatus includes a support structure. A first panel is pivotally coupled to the support structure for pivotal movement between a first position and a second position. A second panel is pivotally coupled to the support structure for pivotal movement between a first position and a second position. A lock is operably coupled to the first panel and the second panel to retain the first panel in the first position when the second panel is in the second position and to retain the second panel in the first position when the first panel is in the second position.

According to another aspect of this disclosure, a telecommunications enclosure includes a housing. A first panel is operatively coupled to the housing for pivotal movement between a first position and a second position. A second panel operatively coupled to the housing for pivotal movement between a first position and a second position. The telecommunications enclosure includes a lock operable to retain the first panel in the first position when the second panel is in the second position and to retain the second panel in the first position when the first panel is in the second position. The telecommunications enclosure includes at least one fiber optic splitter mounted on the first panel and a termination field mounted on the second panel.

According to another aspect of this disclosure, a lock includes housing having a first slot for receiving a first catch and a second slot for receiving a second catch. The lock is adapted to retain at least one catch at all times.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a top plan view of an apparatus with a lock and two pivotally moveable panels in a first position.

FIG. 2 is an isometric view of the apparatus of FIG. 1 with one panel in a second position.

FIG. 3 a top plan view of another apparatus with a lock and two pivotally moveable panels that pivot about perpendicular axes.

FIG. 4 is a top plan view of another apparatus with a lock and two pivotally moveable panels that pivot about separated parallel axes.

FIG. 5 is a front view of a telecommunications enclosure including two pivotally moveable panels, each in a first position.

FIG. 6 is a front isometric view of the telecommunications enclosure of FIG. 5.

FIG. 7 is a front isometric view of the telecommunications enclosure of FIG. 5 with one panel in a second position.

FIG. 8 is a front view of the telecommunications enclosure of FIG. 7.

FIG. 9 is a front isometric view of a telecommunications enclosure mounted in a pedestal, the enclosure including a lock and two pivotally moveable panels, each pivoted to a different position.

FIG. 10 is a front isometric view of the telecommunications enclosure of FIG. 9 with the two pivotally moveable panels in different positions.

FIG. 11 is a front view of the telecommunications enclosure of FIG. 10.

FIG. 12 is a lock having slots to receive two catches and adapted to retain at least one catch at all times.

FIG. 13 is an exploded view of the lock of FIG. 12.

FIG. 14 is another exploded view of the lock of FIG. 12.

FIG. 15 is an isometric view of a catch for use with the lock in FIG. 12.

FIG. 16 is a cross-sectional view of the lock in FIG. 12 with two catches retained by the lock.

FIG. 17 is an isometric view of the lock in FIG. 12 retaining one catch.

FIG. 18 is a cross-sectional view of the lock in FIG. 12 as one of two catches retained by the lock is being released.

FIG. 19 is a cross-sectional view of the lock in FIG. 12 after one of two catches retained by the lock is released.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

According to one aspect of this disclosure, an apparatus includes a support structure. A first panel is pivotally coupled to the support structure for pivotal movement between a first position and a second position. A second panel is pivotally coupled to the support structure for pivotal movement between a first position and a second position. A lock is operably coupled to the first panel and the second panel to retain the first panel in the first position when the second panel is in the second position and to retain the second panel in the first position when the first panel is in the second position.

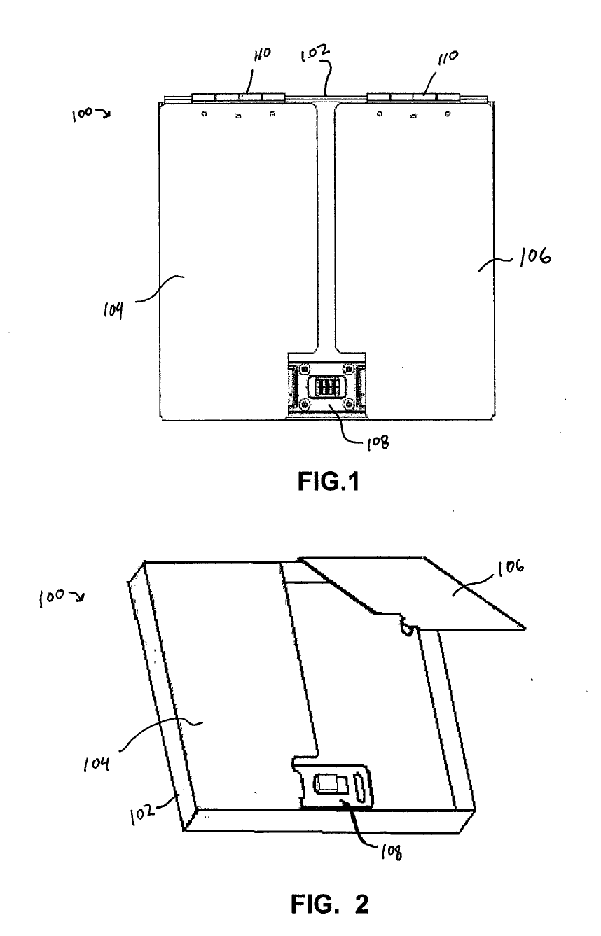

One example of an apparatus, generally indicated by the reference numeral 100, according to the aspect disclosed above is illustrated in FIGS. 1 and 2. The apparatus 100 includes a support structure 102, a first panel 104, a second panel 106 and a lock 108. The first and second panels 104, 106 are each pivotally coupled the support structure 102 for pivotal movement between their first positions and second positions. In FIG. 1, the first and second panels 104, 106 are illustrated in their first positions. In FIG. 2, however, the second panel 106 has been pivotally moved to a second position.

The support structure may be any structure capable of supporting the panels 104, 106. For example, the support structure may be a box, an enclosure, a wall, a refrigerator, a table, a beam, etc.

The panels 104, 106 may be any type of pivotally moveable panels. For example, the panels 104, 106 may be doors, panels for mounting something to, dividers, etc.

The panels 104, 106 may be coupled to the support structure 102 by direct connection to the support structure 102 or by indirect connection. For example, the panels 104, 106 may be directly connected using a connector that permits pivotal movement of the panels 104, 106. For example, the panels 104, 106 may be bolted to the support structure 102 with a single bolt, screw, rivet, nail, etc. The panels 104, 106 may include hinges, either separate hinges attached to the panels or monolithically formed with the panels, that are directly attached to the support structure 102 using screws, nails, bolts, welds, glue, rivets, etc. The panels 104, 106 in FIGS. 1 and 2 are directly connected to the support structure 102 by hinges 110. Alternatively, the panels 104, 106 may be attached, for example, to a mounting plate that is directly connected to the support structure 102.

The lock 108 is mounted to the support structure 102 and retains one or both panels in their respective first position. As illustrated in FIG. 1, the lock 108 retains both the first and second panels 104, 106 in their first positions. In FIG. 2, the lock 108 retains the first panel 104 in its first position while the second panel 108 is in its second position. Similarly, but not illustrated, the lock retains the second panel 106 in its first position when the first panel is in a second position. In at least one embodiment, the lock is configured to always retain at least one of the first and second panels 104, 106 in its first position. In such an embodiment, when one of the panels 104, 106 is not in the first position (i.e., it is in a second position), the other panel 104, 106 is retained in its first position. The lock prevents moving the panel in the first position from being pivotally moved from the first position until the other panel is returned to the first position. One example lock for use in apparatus such as discussed above will be discussed below. However, any other appropriate lock may be used.

Although the panels are illustrated oriented vertically with a hinge at the top in FIG. 1, any orientation is possible. The apparatus 100 in FIG. 1 may be rotated any amount from zero to three hundred sixty degrees from that illustrated in FIG. 1 without departing from the scope of this disclosure.

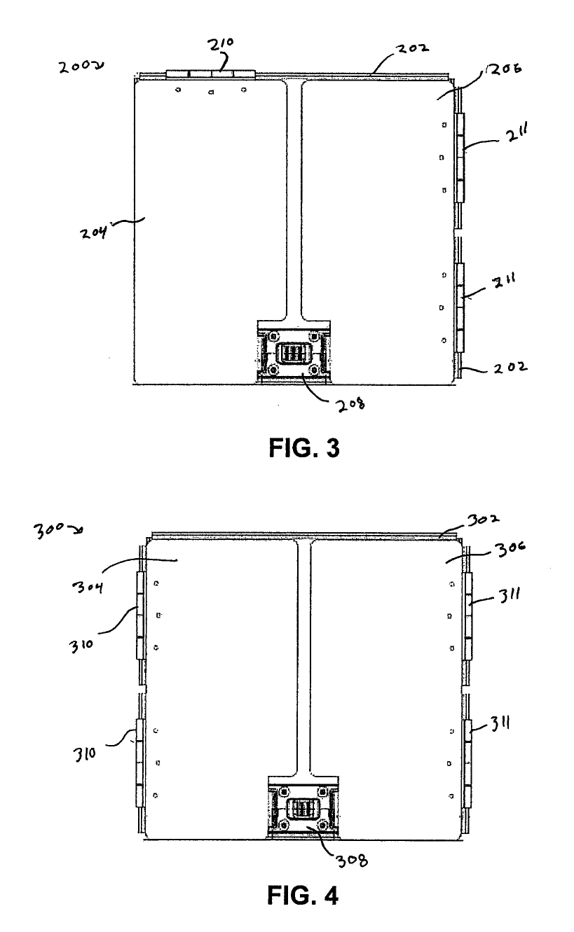

Additionally, the panels 104, 106 need not pivotally move in the same direction or about the same axis. FIGS. 3 and 4 illustrate additional example apparatus 200, 300.

The apparatus 200 has panels 204, 206, each pivotally coupled to a support structure 202 for pivotal movement between respective first positions and second positions, and includes a lock 208 similar to the lock 108. The panels 204, 206, however are coupled to the support structure to pivot in different directions, about different axes. Panel 204 is coupled to the support structure 202 at the top by hinge 21, while panel 206 is coupled to the support structure 202 by hinges 211 along its right side. Accordingly, panels 204 and 206 will pivot about axes that are substantially perpendicular to each other.

Similarly, the apparatus 300 has panels 304, 306, each pivotally coupled to a support structure 302 for pivotal movement between respective first positions and second positions, and includes a lock 308 similar to the lock 10. Panels 304, 306 are coupled to pivot about different axes, however. Panel 304 is coupled to the support structure 302 along its left side by hinges 310, while panel 306 is coupled to the support structure along its right side by hinges 311. Accordingly, panels 304 and 306 will pivot about axes that are substantially parallel to, but separated from, each other.

According to another aspect of this disclosure, a telecommunications enclosure includes a housing. A first panel is operatively coupled to the housing for pivotal movement between a first position and a second position. A second panel operatively coupled to the housing for pivotal movement between a first position and a second position. The telecommunications enclosure includes a lock operable to retain the first panel in the first position when the second panel is in the second position and to retain the second panel in the first position when the first panel is in the second position. The telecommunications enclosure includes at least one fiber optic splitter mounted on the first panel and a termination field mounted on the second panel.

In one embodiment, the housing defines an internal space. The first and second panels are located within the internal space when in their first positions. The housing may further define at least one opening to the internal space and the telecommunications enclosure may include a door. The door is pivotally coupled to the housing for covering the opening.

In one embodiment, the lock is further configured to selectively simultaneously retain the first and second panels in their first positions. Additionally, or alternatively, the lock may be operable to prevent the first and second panels from simultaneously being pivotally moved from their first positions.

The panels' first positions may be closed positions. In such closed positions, accessing the rear side of the first and second panels is prevented. Alternatively, the first positions may be open positions allowing access to the rear side of the panels.

In one embodiment, the first and second panels pivot about vertical axes. Alternatively, the panels may pivot about axes that are horizontal, angled between vertical and horizontal, a combination of horizontal, vertical and/or angled, etc.

In one embodiment, the first and second panels pivot about vertical axes that are substantially aligned and the first panel is positioned above the second panel. Alternatively, the panels may pivot about axes that are not aligned and may be positioned in any other suitable manner (such as, beside each other, second panel above first panel, etc.).

In one embodiment, the telecommunications enclosure housing is a fiber distribution hub.

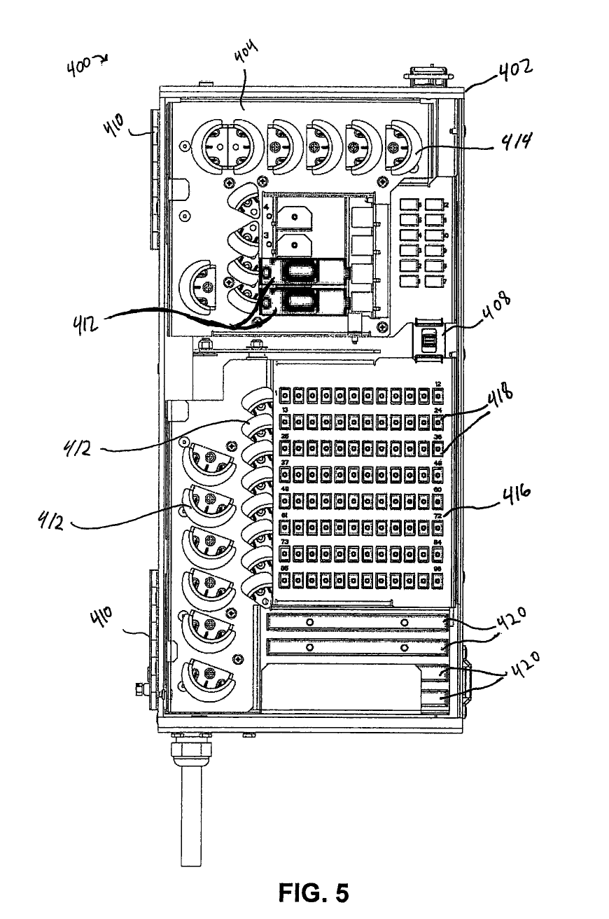

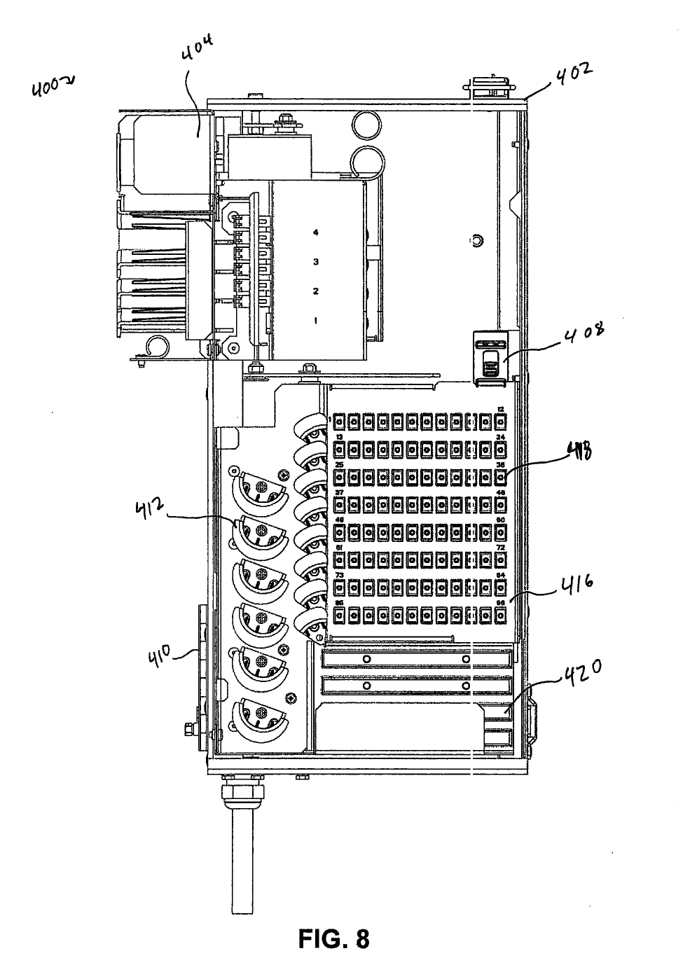

An example telecommunications enclosure 400 according to one or more aspect of this disclosure is illustrated in FIGS. 5-8. It should be understood, however, that the aspects discussed above can be practiced with a wide variety of different components, in a wide variety of different apparatus, and that the aspects discussed above are not limited to the particular example discussed hereinafter.

The telecommunications enclosure 400 includes a housing 402. The housing may be constructed of any suitable material, such as, for example, metal, plastic, fiberglass, etc. The housing 402 forms a generally rectangular box defining an interior space.

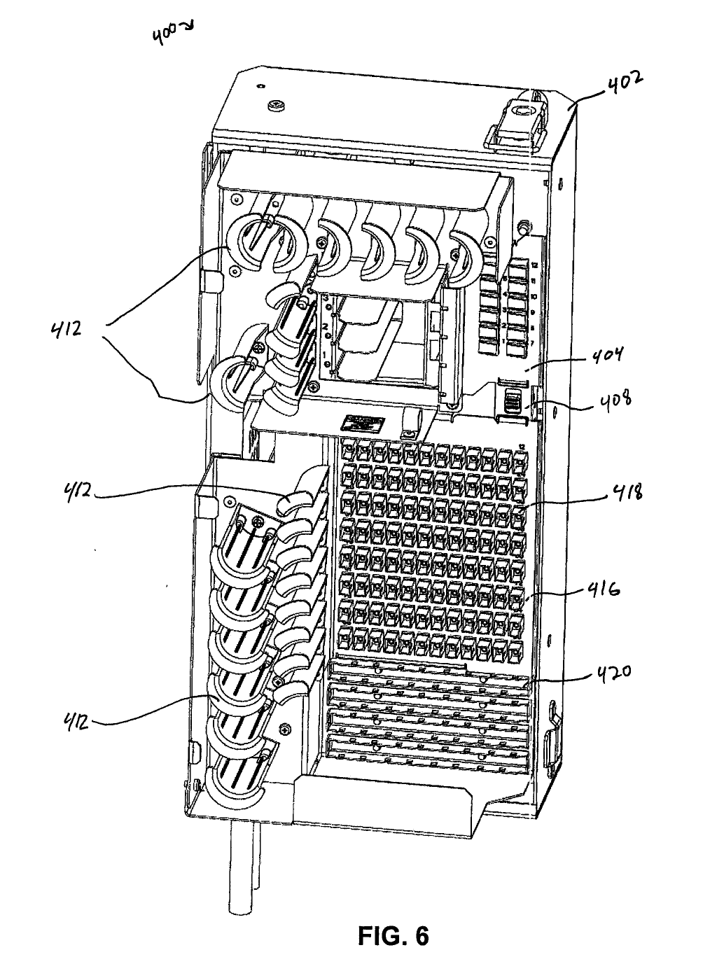

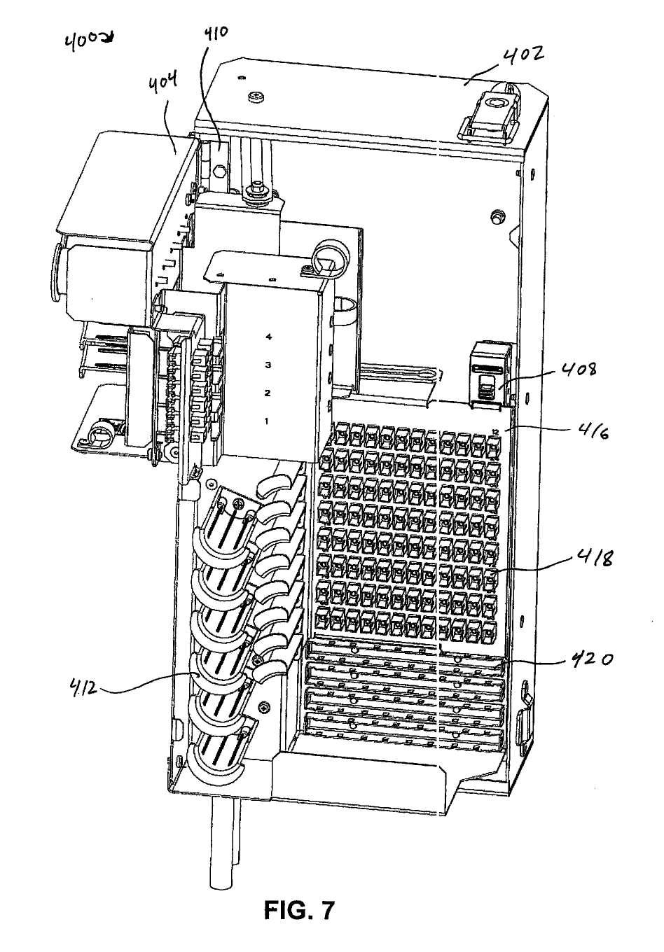

A first panel 404 and a second panel 406 are operatively coupled to the housing 402. The panel 404 may be pivotally moved between a first position (illustrated in FIGS. 5 and 6) and a second position (illustrated in FIGS. 7 & 8). Similarly, second panel 406 may also be pivotally moved between a first position (illustrated in FIGS. 5 and 6) and a second position (not illustrated). Although only two positions are illustrated, the panels 404, 406 may be pivotally moved to any position between their first position and the second position. Further, the panels 404, 406 may be pivotally moved to any position (which is still a second position) permitted by the attachment to the housing and interaction between the first panel, or parts mounted on the first panel, and other components of the telecommunications enclosure 400. Although illustrated positioned with the first panel 404 above the second panel 406, the panels 404, 406 may be arranged in other orientations, such as beside each other, the first panel 404 beneath the second panel 406, etc.

The panels 404, 406 are each coupled to the housing 402 by a hinge 410. Although each of the panels 404, 406 is coupled to the housing by only a single hinge 410 in the example of FIGS. 5-8, more than one hinge may be used. The hinge 410 may be any type of hinge that allows pivotal movement of the panels 404, 406 relative to the housing 402. The pivotal movement permitted by the illustrated hinge 410 is pivotal movement about a single axis. However, the hinge 410 may also be a hinge that permits movement about multiple axes, or any other appropriate type of pivotal movement. The hinges 410, as shown, are separate hinges mechanically fastened to the panels 404, 406 and the housing 402. The hinge 410 may also be monolithically (or integrally) formed with the panel 404, 406, the housing 410, or both. The hinges 410 in the example of FIGS. 5-8 are located on the left side of the panels 404, 406 and the enclosure 402 and permit pivotal movement of the panels 404, 406 about vertical axes that are substantially aligned with each other. As with the apparatus 100, 200, 300 discussed above, however, the hinges may be located to allow pivotal movement about different axes, such as parallel but separated axes, perpendicular axes, etc.

Although the panels 504, 506 are connected to the housing 502 by hinges 510, it should also be noted that the panels 504, 506 may be coupled to the housing 502 by direct connection to the housing 502 or by indirect connection. For example, the panels 504, 506 may be directly connected using a connector that permits pivotal movement of the panels 504, 506. The panels 504, 506 may include have separate hinges 510 attached to the panels or hinges 510 monolithically formed with the panels 504, 506. The hinges 510 may be directly attached to the housing 502 using screws, nails, bolts, welds, glue, rivets, etc. Alternatively, the panels 504, 506 may be attached, for example, to a mounting plate that is directly connected to the housing 502.

The panels 404, 406 include various telecommunications distribution components coupled to them. For example, as shown in FIG. 5 only, first panel 404 includes fiber optic cable splitters 412 mounted thereon. The fiber optic cable splitters 412 each receive a distribution fiber and provide a larger number of fiber optic cables for distribution or connection. Spaces for two additional splitters are located above splitters 412. Accordingly, the example of FIGS. 5-8 could include between zero and four optical fiber splitters. It should be recognized, however, that configurations with more or fewer optical splitters are possible and the telecommunications enclosure is not limited to any one such a configuration.

The second panel 406 includes a subscriber termination field 416 mounted thereon. The subscriber termination field 416 is used to connect fiber optic cable from the splitter to a subscriber's premises. For example, the termination field 416 includes 96 connection points 418. Each connection point 418 may be connected, by fiber optic cable, to a subscriber's, or potential subscriber's, premises (an office, an apartment, a house, etc.). The connection points 418 connected to the premises of a person who is to receive services (such as cable television, telephone service, internet connectivity, etc.) via the fiber optic cable is connected to a cable from the splitter 412. Not all connection points are necessarily connected to a subscriber, or potential subscriber, and not all potential subscribers are subscribers who are to receive services via the fiber optic cable. Accordingly, some of the connection points 418 may not be connected to any premises and some of the connection points may be connected to premises, but not be connected to cable any incoming fiber optic cable (e.g., cable from the splitter 412). Although the termination field 416 in FIGS. 5-8 includes 96 connection points, in other embodiments the termination field 416 includes 72 or 144 connection points. It should be recognized, however, that configurations with more or fewer connection points are possible and the mounting plate is not limited to any one such a configuration.

Any other appropriate telecommunications components may also be mounted to the panels 404, 406. For example, wire routing guides 414 (also sometimes variously known as radius limiting spools, half spools, crescent spools, etc.) are mounted to the first and second panels 404, 406. The wire routing guides 414 are used to retain and route wire or fiber optic cable between locations of the telecommunications enclosure 400 and to hold excess wire or cable. The second panel also includes four parking strips 420 mounted thereon. The parking strip 420 are used to hold (or “park”) unused (i.e., not currently connected to any subscriber's connection point 418) fiber optic cable. Additionally, or alternatively, unused distribution cable may be parked on a connection point 418 that is not connected to any subscriber's premises.

The telecommunications enclosure 400 will include, at least when installed and/or in use, fiber optic cable routed throughout the telecommunications enclosure 400. In particular there is typically fiber optic cable and/or fiber along the front and/or back side of the panels 404, 406. Every time connections and/or fiber are disturbed (e.g., by human hands, panels moving, components touching them, etc.) stress and strain is placed on the fiber and the connections. Accordingly, avoiding disturbing fiber optic cable, and its connections, is preferred where possible. However, as new subscribers or potential subscribers are added, old subscribers are dropped, additional interconnections connections made, etc. The connections, interconnections, routing etc. in the telecommunications enclosure 400 may need to be altered.

The telecommunications enclosure 400 permits access to the front and back of the panels 404, 406 in a limited manner. Both panels 404, 406 can pivot (or swing) to allow access to both sides (i.e. the front and rear) of the panels 404, 406. However, the panels 404, 406 are separately pivotable. Both panels 404, 406 do not need to be pivotally moved to access the rear of only one panel 404, 406. This allows a technician to access the rear of one panel 404, 406 without disturbing the fiber connected to, or located in front/behind, the other panel 404, 406.

Furthermore, the telecommunications enclosure 400 includes a lock 408 that retains one panel 404, 406 in its first position when the other panel 404, 406 is in its second position. Accordingly, only one of the first and second panels 404, 406 may be pivoted at any time. To pivot the other panel 404, 406, the pivoted panel must be returned to its first position. This limitation of movement may prevent undue wear and tear on the fiber optic cable and its connections.

The lock 408 can also simultaneously retain the panels 404, 406 in their first positions. Thus, the lock 408 prevents the panels 404, 406 from pivotally moving when such movement is not desired. When a technician does desire to pivot one of the panels 404, 406, the technician can actuate the lock 408 to selectively release one of the panels 404, 406 and allow the selected panel 404, 406 (and only the selected panel) to be pivotally moved. One lock 408 appropriate for use in the telecommunications enclosure 400 is discussed below. It should be recognized, however, that other locks are possible and the telecommunications enclosure 400 is not limited to any one such lock.

The telecommunications enclosure 400 may mountable in any appropriate location/configuration. For example, the telecommunications enclosure 400 is configured for mounting in an indoor location. It may be mounted on an interior wall, floor, post, etc. Other embodiments, however, are configured for mounting in exterior locations. Such embodiments may be mounted, for example on a pole, a pedestal, a pad, a vault, and exterior wall, etc.

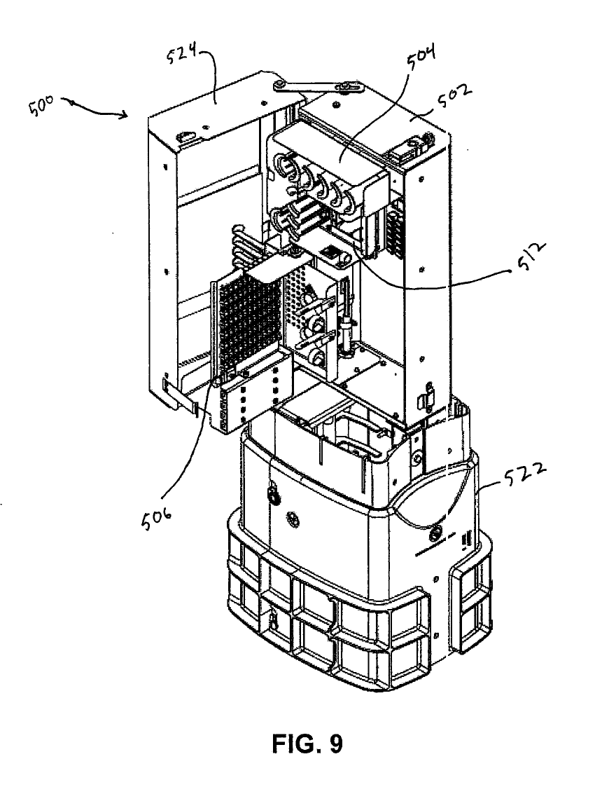

Another example telecommunications enclosure 500 according to one or more aspect of this disclosure is illustrated in FIGS. 9-11. The telecommunications enclosure 500 is similar to the telecommunications enclosure 400, but is configured for exterior use mounted in a pedestal 522.

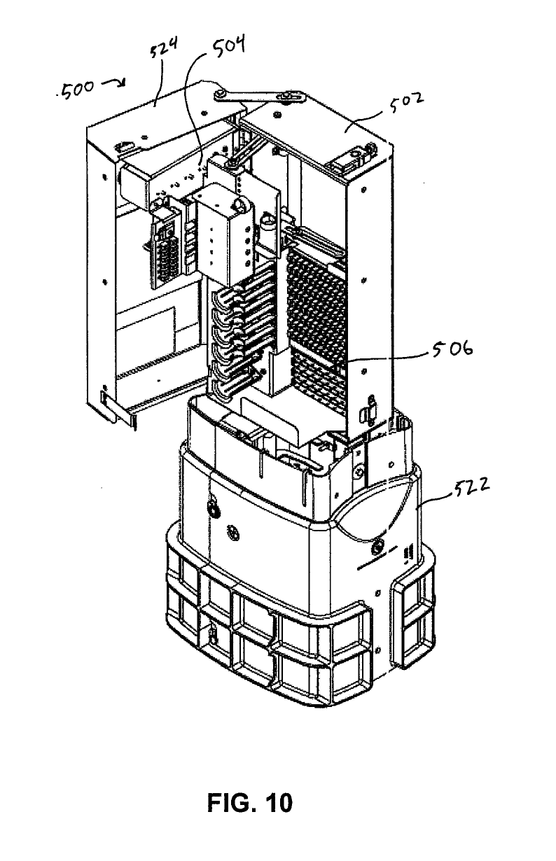

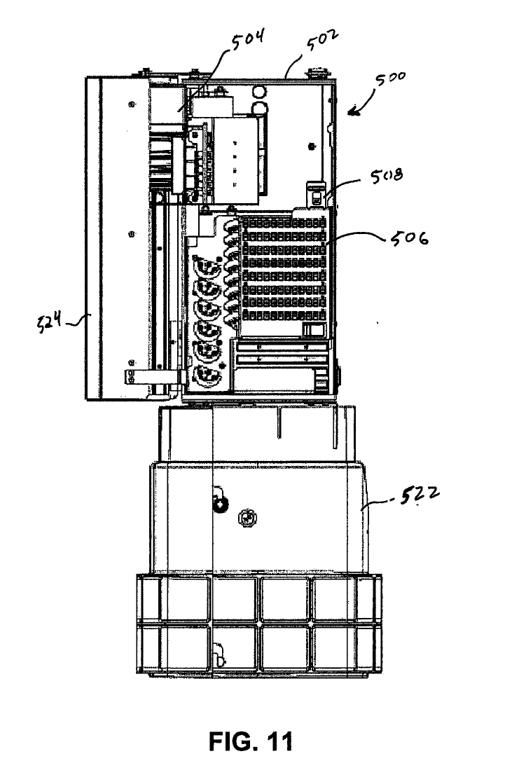

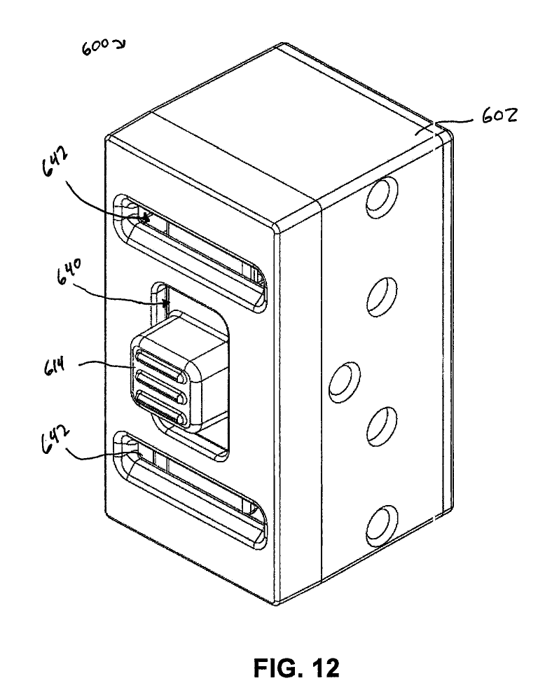

The telecommunications enclosure 500 includes a housing 502 that forms a generally rectangular box defining an interior space. A door 524 is mounted to the housing 502. The door 524 is operable to open and close to expose and enclose (respectively), the interior space defined by the housing 502. A first panel 504 and a second panel 506 are operatively coupled to the housing 502. The panel 504 may be pivotally moved between a first position (illustrated in FIG. 9) and a second position (illustrated in FIGS. 10 and 11). Similarly, second panel 506 may also be pivotally moved between a first position (illustrated in FIGS. 10 and 11) and a second position (illustrated in FIG. 9). As with the panels 404, 406, the panels 504, 506 can include various telecommunications distribution components coupled to them. For example, first panel 504 includes a fiber optic cable splitter 512 mounted thereon and the second panel 506 includes a subscriber termination field 516 mounted thereon. Any other appropriate telecommunications components may also be mounted to the panels 504, 506.

The telecommunications enclosure 500 includes a lock 508 (visible in FIG. 11) that retains one panel 504, 506 in its first position when the other panel 504, 506 is in its second position. Accordingly, only one of the first and second panels 504, 506 may be pivoted at any time. To pivot the other panel 504, 506, the pivoted panel must be returned to its first position. This limitation of movement may prevent undue wear and tear on the fiber optic cable and its connections.

The lock 508 can also simultaneously retain the panels 504, 506 in their first positions. Thus, the lock 508 prevents the panels 504, 506 from pivotally moving when such movement is not desired. When a technician does desire to pivot one of the panels 504, 506, the technician can actuate the lock 408 to selectively release one of the panels 504, 506 and allow the selected panel 504, 506 (and only the selected panel) to be pivotally moved. One lock 508 appropriate for use in the telecommunications enclosure 500 is discussed below. It should be recognized, however, that other locks are possible and the telecommunications enclosure 500 is not limited to any one such lock.

According to another aspect of this disclosure, a lock includes housing having a first slot for receiving a first catch and a second slot for receiving a second catch. The lock is adapted to retain at least one catch at all times.

In one embodiment, the lock also includes a latch slidably coupled to the housing. The latch is slidably moveable between a first position for engaging the first catch, a second position for engaging the second catch and a third position for engaging the first catch and the second catch.

According to other embodiments, the lock includes a first stop coupled to the housing to retain the latch in the second position when the first catch is not within the first slot. The lock also includes a second stop coupled to the housing to retain the latch in the first position when the second catch is not within the second slot.

In some embodiments, the first stop and the second stop are retractable stops extendable between a retracted position that does not interfere with movement of the latch and an extended position that prevents the latch from being moved past the stop. Insertion of the first catch into the first slot slidably moves the first stop toward the retracted position and insertion of the second catch into the second slot slidably moves the second stop toward the retracted position. In one embodiment, the first and second stops are in the retracted position when the latch is in the third position.

In at least one embodiment, the first and second stops each include two retractable stop elements. Other embodiments, however, may include more or fewer stop elements.

An example lock 600 according to one or more aspect of this disclosure described with reference to FIGS. 12-18. It should be understood, however, that the aspects discussed above can be practiced with a wide variety of different locks, and that the aspects discussed above are not limited to the particular example discussed hereinafter.

The lock 600 includes a housing 602. The housing contains the working components of the lock and defines a size of the lock. The housing 602, and accordingly the lock 600, is not limited to the size and/or proportions illustrated in the figures and may be any appropriate size and have any appropriate proportions. The housing 602 may be constructed from any suitable materials, including, for example, metal, plastic, fiberglass, etc.

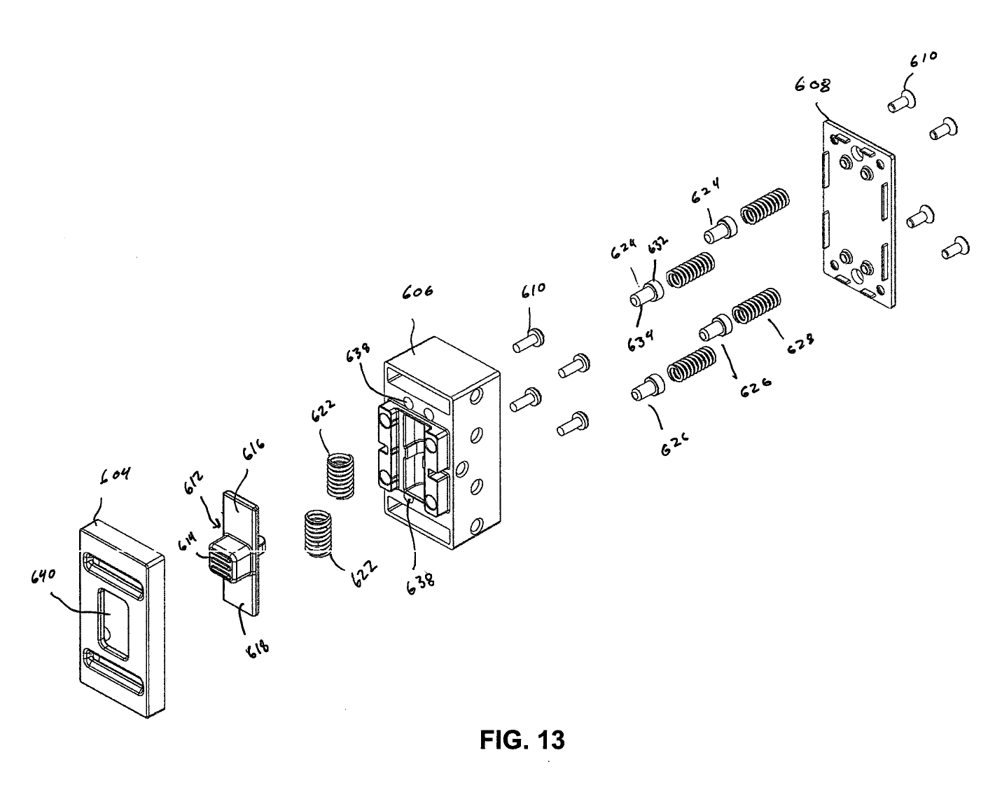

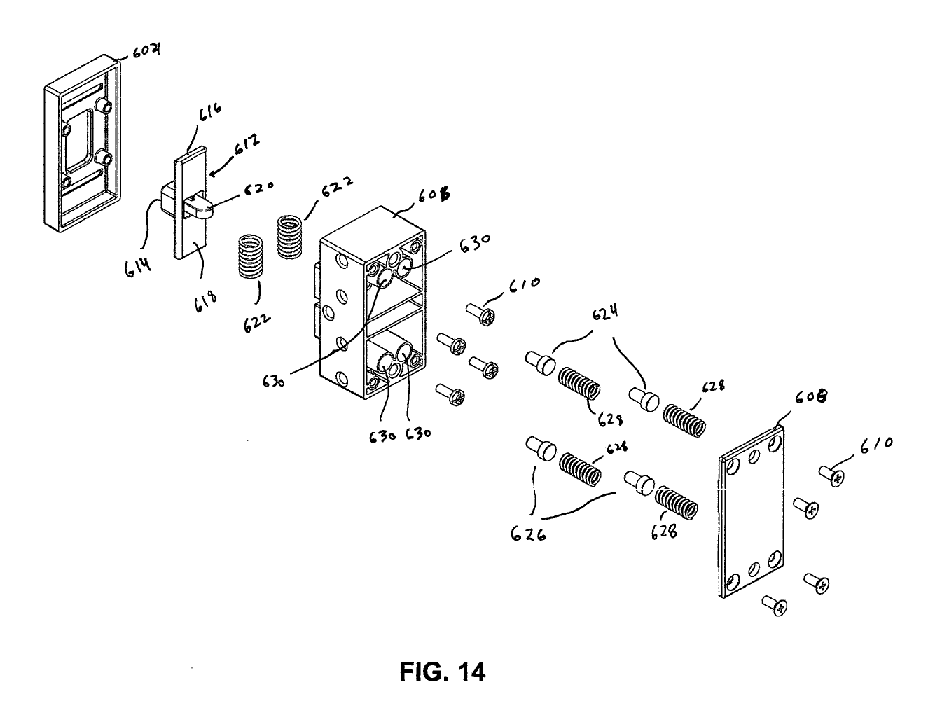

As can be seen in FIGS. 13 and 14, the housing 602 is made of three pieces. A top 604, a middle 606 and a bottom 606 are connected using screws 610. Alternatively, the housing 602 may have more or fewer components and the components may be fastened by any appropriate fastening method (such as screws, glue, welding, etc.).

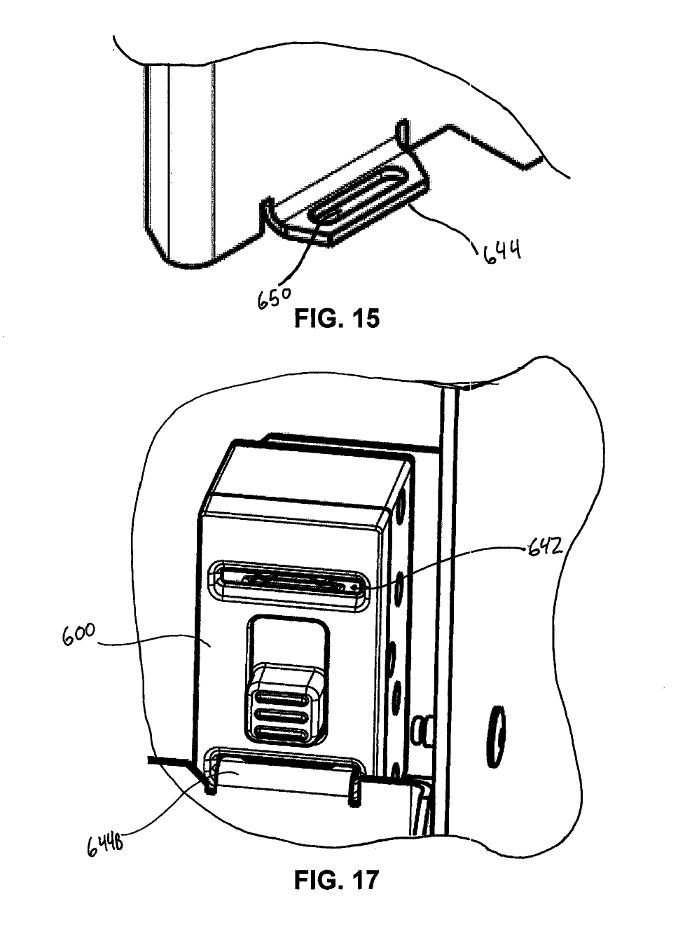

A latch 612 is slidably retained within the housing 602. The latch includes a knob 614, a first tongue 616 and a second tongue 618. When assembled, the knob 614 extends through an opening 640 in the upper portion 604 of the housing 602. The knob 614 is used to actuate the lock 600 to selectively retain two catches, a first catch or a second catch. Slot 642 in the housing 602 permit a catch (such as catch 644 in FIG. 15) to enter the housing to be retained by the latch 612. The tongues 616, 618 are the portion of the latch that engages a catch to be retained. The latch also includes a biasing knob 620. Two biasing members (e.g. springs) 622 are captured within the housing 602 and apply biasing forces in opposite directions to the biasing knob 620.

A first pair of retractable stops 624 and a second pair of retractable stops 626 are also retained within the housing 602. The stops 624, 626 are generally cylindrical shaped and are slidably held within cylindrical channels 630 in the middle portion 606. The stops 624, 626 have a base portion 632 with a larger diameter than a body portion 634 of the stop 634, 636. Openings 638 in a top face of the middle portion 606 permit the body 634 of the stops 624, 626 to extend above the middle portion, but are too small to allow the base portions 632 to pass through. Each stop 624, 626 is biased toward the top 604 of the housing 602 and through the openings 638 by a stop biasing member 628. Because stop biasing members 628 are compressible, however, the stops 624, 626 may be pushed back down the channels 630 (i.e., retracted).

When assembled, the biasing members 622 apply opposite biasing forces to the biasing knob 620 to maintain the latch 612 in a middle position (such as shown in FIG. 12). In the middle position, the tongues 616, 618 overlie the first stops 624 and the second stops 626. Accordingly, the stops 624, 626 are not able to extend out of the channels 630 beyond the latch 612 and the stop biasing members 628 are partially compressed.

When a user applies a force to the knob 614 to slide it along the opening 640, one of the tongues 616, 618 is moved away from overlapping the stops 624, 626 underneath that tongue 616, 618. The partially compressed biasing member 628 underneath the uncovered stop 624, 626 decompress and slide the stop toward the top portion 604 until the body 634 of the stop extends at least above the level of the bottom of the removed tongue 616, 618. In this position, the latch 612 cannot be slid back to the middle position because the extended stop 624, 626 is located above the level of the removed tongue 616, 618. Accordingly, the extended stop 624, 626 must be retracted below the level of the tongue 616, 618 before the latch 612 can be returned to the middle position. As will be described below, the extended stop 624, 626 is retracted by insertion of a catch 644 through slot 642 that overlies the extended stop 624, 626.

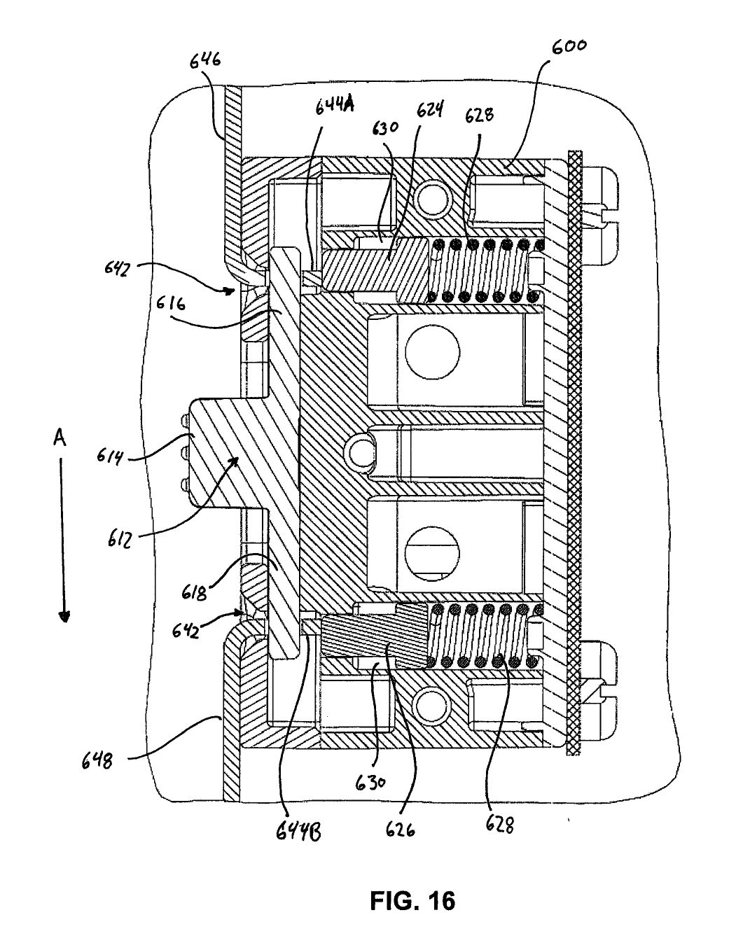

FIG. 16 illustrates a cross-section view of the assembled lock 600 in use with a first catch 644A and a second catch 644B (collectively, catches 644). The catches 644 are illustrate as part of a first panel 646 and a second panel 648, but may separate catches attached to a panel and/or may be used with items other than panels. Both catches 644 are inserted through the slots 642. The tongues 616, 618 are each positioned through catch openings 650 (best seen in FIG. 15) in catches 644 and the latch 612 is in the middle position. Accordingly, both catches 644 are retained by the lock 600 and both panels 646, 648, which are coupled to the catches 644, are retained in their current position. The stops 626, 628 are held in their retracted positions in the channels 630 by the catches 644 and biasing members 628 are partially compressed.

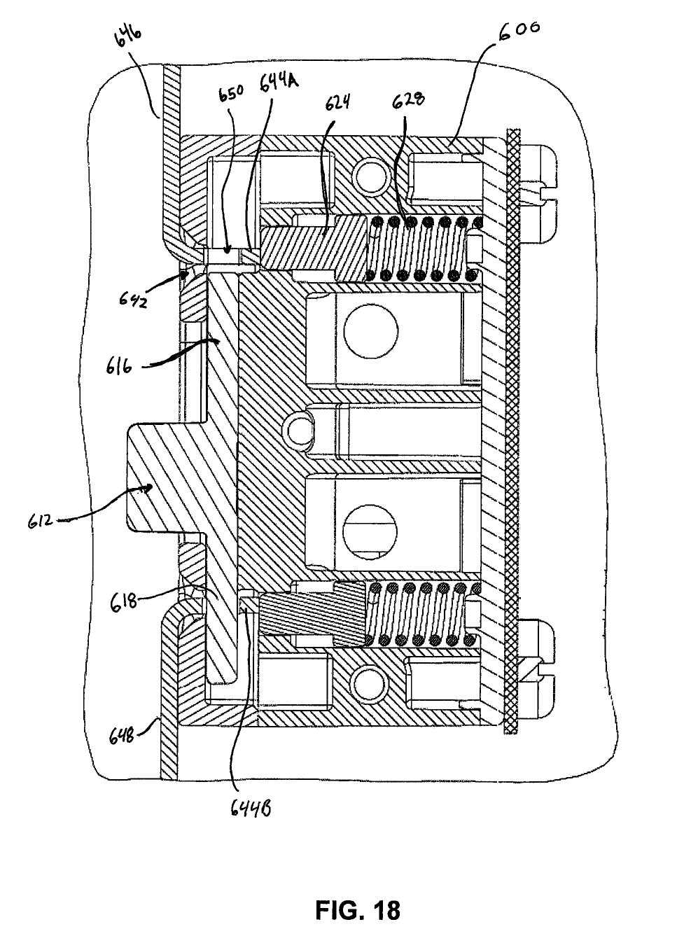

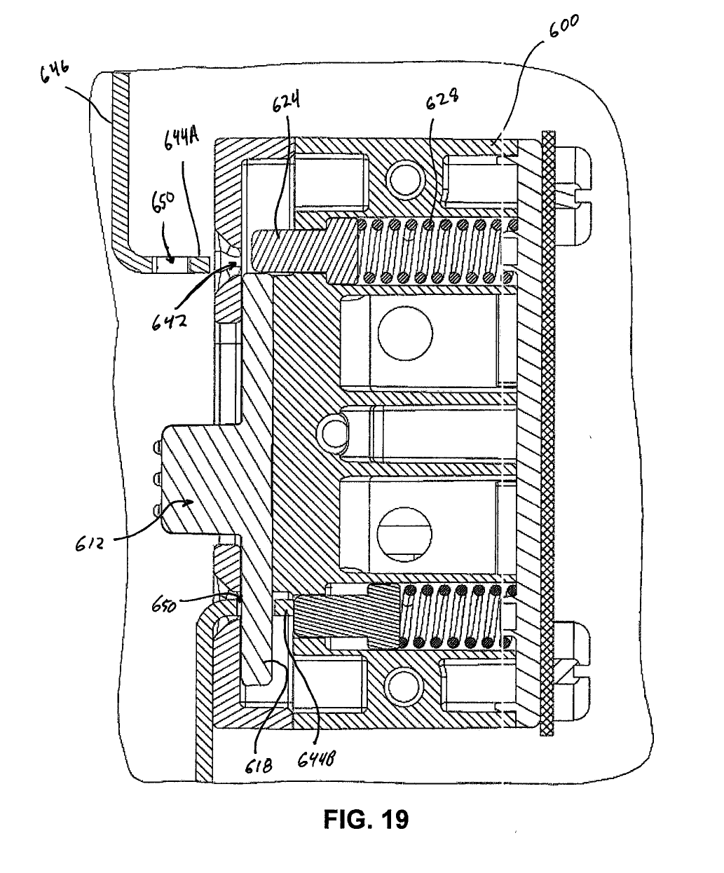

A user can apply a force to the knob in a direction A to release catch 644A, and accordingly first panel 646. The result is illustrated in FIGS. 17-19. In FIG. 18, the knob 612 has now been moved to a position below the middle position. The second tongue 618 still passes through the catch opening 650 in the catch 644B and, therefore still retains catch 644B and the second panel 648. The first tongue 616, however, no longer passes through the catch opening 650 in catch 644A and catch 644A may be removed from slot 642. FIGS. 17 and 19 illustrate the result when the catch 644A is removed from the slot 642. As can be seen, the stop biasing member 628 has extended from its compressed state and caused stop 624 to slide through openings 638 to an extended position. Depending on the orientation of the lock and catch and the forces being applied to the catch (e.g., the weight of the panel 646, weight of the catch, force a person is applying to the catch, etc), the stop biasing member 628 may apply enough force to cause the catch 644A to rise out of the slot 642 automatically when the latch is moved to the position in FIGS. 18 and 19. The body 634 extends above the level of the bottom of the first tongue 616. Hence, the latch 612 cannot be returned to the middle position. Accordingly, the second catch 644B cannot be removed from the lock 600 while the stop 624 is extended. Reinserting the catch 644A into the slot 642 applies a biasing force against the stop 624 (and opposed to the biasing force of the stop biasing member 628) to force stop 624 into the retracted position. Once the first catch 644A is fully (or substantially fully) reinserted, the first tongue 616 may pass through the catch opening 650 in the first catch 644A and the latch may return to the middle position illustrated in FIG. 16.

As mentioned above, biasing members 622 (not visible in the cross-section figures) apply complimentary biasing forces to the bias knob 620. These forces bias the latch toward the middle position. When a user slides the knob, for example, in direction A, one of the biasing members 622 (the one in the direction to which the latch is sliding) is compressed by the biasing knob 620. The extended stop 624 not only prevents the latch 612 from being moved back to the middle position, but also prevents bias member 622 from expanding and forcing the latch 612 back to the middle position. When the first catch 644A is reinserted, the stop 624 is retracted, and the catch opening 650 aligns with the first tongue 616. The resistance to the biasing force of the compressed biasing member 622 is removed and the biasing member can expand to slide the first tongue 616 through the catch opening 650 and force the latch back to the middle position illustrated in FIG. 16. Hence, the lock 600 automatically relocks when the removed catch (in this example, catch 644A) is reinserted through the slot 642.

Releasing the second catch 644 Band reinserting/relatching the second catch occurs in the same manner as discussed above for the first catch 644A.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. An apparatus comprising:
a support structure;
a first panel pivotally coupled to the support structure for pivotal movement between a first position and a second position;
a second panel pivotally coupled to the support structure for pivotal movement between a first position and a second position; and
a lock operably coupled to the first panel and the second panel for retaining the first panel in the first position when the second panel is in the second position and for retaining the second panel in the first position when the first panel is in the second position.

2. The apparatus of claim 1 wherein the lock is adapted for selectively retaining both the first panel in the first position and the second panel in the second position.

3. The apparatus of claim 1 wherein the lock is configured for selectively retaining the first panel in the first position when the second panel is in the second position and for retaining the second panel in the first position when the first panel is in the second position.

4. The apparatus of claim 3 wherein the lock is configured to always retain at least one of the first panel in the first position and the second panel in the first position.

5. A lock comprising:
a housing including a first slot for receiving a first catch and a second slot for receiving a second catch, the lock adapted to retain at least one catch at all times.

6. The lock of claim 5 further comprising a latch slidably coupled to the housing, the latch slidably moveable between a first position for engaging the first catch, a second position for engaging the second catch and a third position for engaging the first catch and the second catch.

7. The lock of claim 6 further comprising a first stop coupled to the housing to retain the latch in the second position when the first catch is not within the first slot, and a second stop coupled to the housing to retain the latch in the first position when the second catch is not within the second slot.

8. The lock of claim 7 wherein the first stop and the second stop are retractable stops extendable between a retracted position that does not interfere with movement of the latch and an extended position that prevents the latch from being moved past the stop.

9. The lock of claim 8 wherein insertion of the first catch into the first slot slidably moves the first stop toward the retracted position and insertion of the second catch into the second slot slidable moves the second stop toward the retracted position.

10. The lock of claim 8 wherein both of the first and second stops are in the retracted position when the latch is in the third position.

11. The lock of claim 7 wherein the first and second stops each include two retractable stop elements.

12. A telecommunications enclosure comprising:
a housing;
a first panel operatively coupled to the housing for pivotal movement between a first position and a second position;
a second panel operatively coupled to the housing for pivotal movement between a first position and a second position;
a lock operable to retain the first panel in the first position when the second panel is in the second position and to retain the second panel in the first position when the first panel is in the second position;
at least one fiber optic splitter mounted on the first panel; and
a termination field mounted on the second panel.

13. The telecommunications enclosure of claim 12 wherein the housing defines an internal space, the first and second panels located within the internal space when in their first positions.

14. The telecommunications enclosure of claim 13 wherein the housing further defines at least one opening to the internal space, and the telecommunications enclosure further comprises at least one door pivotally coupled to the housing for covering the opening.

15. The telecommunications enclosure of claim 12 wherein the lock is further configured to selectively simultaneously retain the first and second panels in their first positions.

16. The telecommunications enclosure of claim 12 wherein the lock is further operable to prevent the first and second panels from simultaneously being pivotally moved from their first positions.

17. The telecommunications enclosure of claim 16 wherein the first and second panels' first positions are closed positions preventing access to a rear side of the first and second panels.

18. The telecommunications enclosure of claim 16 wherein the first and second panels pivot about vertical axes.

19. The telecommunications enclosure of claim 18 wherein vertical axes are substantially aligned and the first panel is positioned above the second panel.

20. The telecommunications enclosure of claim 12 wherein the housing is a fiber distribution hub.
